(19) United States
(12) Patent Application Publication
(10) Pub. No.: US 2023/0243778 A1
(43) Pub. Date: Aug. 3, 2023

(54) SELF-ALIGNED SURFACE MODIFICATION FOR MAGNETOCHEMICAL SENSORS

(71) Applicant: Western Digital Technologies, Inc., San Jose, CA (US)

(72) Inventors: Daniel BEDAU, San Jose, CA (US); Neil L. ROBERTSON, Palo Alto, CA (US)

(73) Assignee: Western Digital Technologies, Inc., San Jose, CA (US)

(21) Appl. No.: 17/649,249

(22) Filed: Jan. 28, 2022

(51) Int. Cl. G01N 27/72; G01N 27/416

(52) U.S. Cl. CPC G01N 27/72; G01N 27/416

(57) ABSTRACT

Disclosed herein are detection devices and methods of making them. A detection device comprises a fluid region, a magnetochemical sensor for detecting magnetic particles, and an electrode coupled to the magnetochemical sensor, the electrode for reading the magnetochemical sensor. A surface of a reactive layer situated on the electrode is functionalized to attract the magnetic particles within the fluid region, and/or an area of the fluid region that is not situated over the electrode is functionalized to repel the magnetic particles. The same mask used to pattern the electrode can be used to pattern the reactive layer to ensure alignment with the electrode. Another detection device embeds the reactive layer in the sensor stack and exposes a surface of it via a trench. The exposed surface can be functionalized to attract magnetic particles toward the magnetochemical sensor.

### BACKGROUND

Magnetochemical sensors can be used in various applications to detect the presence of a chemical or biological agent by, for example, detecting the presence of a magnetic particle coupled to the chemical or biological agent. The magnetic particles can be, for example, magnetic nanoparticles, etc.

Because the magnetic particles are small and generate small, localized magnetic fields, one challenge in using magnetochemical sensors is to bring the magnetic particles in close enough proximity to a magnetochemical sensor to allow their magnetic fields to be detected.

### SUMMARY

This summary represents non-limiting embodiments of the disclosure.

In some aspects, the techniques described herein relate to a detection device, including: a fluid region; a magnetochemical sensor for detecting magnetic particles; and an electrode coupled to the magnetochemical sensor, the electrode for reading the magnetochemical sensor, wherein: (a) a reactive layer is situated on the electrode, and a surface of the reactive layer within the fluid region is functionalized to attract the magnetic particles, or (b) an area of the fluid region that is not situated over the electrode is functionalized to repel the magnetic particles, or (c) both (a) and (b).

In some aspects, the techniques described herein relate to a detection device, wherein the reactive layer is situated on the electrode, and the surface of the reactive layer within the fluid region is functionalized to attract the magnetic particles, and wherein a layout of the reactive layer is substantially identical to a layout of the electrode.

In some aspects, the techniques described herein relate to a detection device, wherein the magnetochemical sensor is one of a plurality of magnetochemical sensors included in the detection device.

In some aspects, the techniques described herein relate to a detection device, wherein the plurality of magnetochemical sensors is arranged in a rectangular array, and wherein the electrode is aligned with a row or a column of the rectangular array.

In some aspects, the techniques described herein relate to a detection device, wherein the reactive layer is situated on the electrode, and the surface of the reactive layer within the fluid region is functionalized to attract the magnetic particles, and wherein the reactive layer includes one or more of ruthenium (Ru), rhodium (Rh), palladium (Pd), silver (Ag), osmium (Os), iridium (Ir), platinum (Pt), or gold (Ag).

In some aspects, the techniques described herein relate to a detection device, wherein the magnetochemical sensor includes: a first ferromagnetic layer; a second ferromagnetic layer; and a spacer layer situated between and coupled to the first ferromagnetic layer and the second ferromagnetic layer.

In some aspects, the techniques described herein relate to a detection device, wherein the magnetochemical sensor includes a magnetoresistive sensor.

In some aspects, the techniques described herein relate to a detection device, wherein the reactive layer is situated on the electrode, and the surface of the reactive layer within the fluid region is functionalized to attract the magnetic particles, and wherein the electrode and the reactive layer are situated over the magnetochemical sensor.

In some aspects, the techniques described herein relate to a method of fabricating a device for detecting magnetic particles, the method including: depositing a sensor stack on a wafer; situating a mask over the wafer; depositing an electrode over the sensor stack; while the mask is in place, depositing a reactive layer over the electrode; and functionalizing the reactive layer to attract the magnetic particles to the reactive layer.

In some aspects, the techniques described herein relate to a method, further including: functionalizing an area of a surface within a fluid region of the device to repel the magnetic particles, wherein the area excludes the reactive layer.

In some aspects, the techniques described herein relate to a detection device for detecting magnetic particles, including: a sensor stack, including: a magnetochemical sensor, and a reactive layer; a trench adjacent to the sensor stack and exposing the reactive layer; and a functionalized surface within the trench, wherein the functionalized surface is configured to direct the magnetic particles toward the sensor stack.

In some aspects, the techniques described herein relate to a detection device, wherein the reactive layer is situated in a cap layer of the sensor stack.

In some aspects, the techniques described herein relate to a detection device, wherein the sensor stack further includes a cap layer, wherein the cap layer includes: a first metal layer, a second metal layer, a third metal layer, and the reactive layer, wherein the third metal layer and the reactive layer are situated between the first metal layer and the second metal layer.

In some aspects, the techniques described herein relate to a detection device, wherein: the first metal layer and the second metal layer include ruthenium (Ru), the third metal layer includes tantalum (Ta), and the reactive layer includes one or more of ruthenium (Ru), rhodium (Rh), palladium (Pd), silver (Ag), osmium (Os), iridium (Ir), platinum (Pt), or gold (Ag).

In some aspects, the techniques described herein relate to a detection device, wherein the reactive layer includes one or more of ruthenium (Ru), rhodium (Rh), palladium (Pd), silver (Ag), osmium (Os), iridium (Ir), platinum (Pt), or gold (Ag).

In some aspects, the techniques described herein relate to a detection device, further including an electrode, and wherein the reactive layer is situated between the magnetochemical sensor and the electrode.

In some aspects, the techniques described herein relate to a detection device, wherein the functionalized surface includes an exposed surface of the reactive layer, and wherein the functionalized surface is functionalized to attract the magnetic particles.

In some aspects, the techniques described herein relate to a detection device, wherein the functionalized surface includes a first zone functionalized to attract the magnetic particles and a second zone functionalized to repel the magnetic particles, and wherein an exposed surface of the reactive layer is included in the first zone.

In some aspects, the techniques described herein relate to a method of fabricating a device for detecting magnetic particles, the method including: depositing a sensor stack, the sensor stack including: a first ferromagnetic layer, a second ferromagnetic layer, a non-magnetic spacer layer situated between the first ferromagnetic layer and the second ferromagnetic layer, and a reactive layer including a reactive metal; creating a trench adjacent to the sensor stack, thereby exposing the reactive layer; and functionalizing a surface within the trench to direct the magnetic particles toward the sensor stack.

In some aspects, the techniques described herein relate to a method, wherein the reactive layer is deposited after depositing the first ferromagnetic layer, the non-magnetic spacer layer, and the second ferromagnetic layer.

In some aspects, the techniques described herein relate to a method, wherein the reactive layer is embedded in a cap layer of the sensor stack, and further including: depositing an electrode over the cap layer.

In some aspects, the techniques described herein relate to a method, wherein functionalizing the surface within the trench to direct the magnetic particles toward the sensor stack includes at least one of (a) functionalizing a first zone to attract the magnetic particles, the first zone including an exposed surface of the reactive layer, or (b) functionalizing a second zone to repel the magnetic particles, wherein the second zone excludes the exposed surface of the reactive layer.

In some aspects, the techniques described herein relate to a method, wherein the first zone and the second zone are non-overlapping.

### BRIEF DESCRIPTION OF THE DRAWINGS

Objects, features, and advantages of the disclosure will be readily apparent from the following description of certain embodiments taken in conjunction with the accompanying drawings in which:

FIG. 1 illustrates a portion of a magnetochemical sensor in accordance with some embodiments.

FIG. 2 illustrates the example magnetochemical sensor of FIG. 1 embedded in a sensor stack in accordance with some embodiments.

FIG. 3A shows a magnetochemical sensor with a magnetic particle over it in accordance with some embodiments.

FIGS. 3B and 3C illustrate how the detected magnetic flux density of the magnetic particle varies with its distance from the magnetochemical sensor.

FIG. 4 is another illustration to illustrate how the detected magnetic field caused by the magnetic particle changes with both vertical distance and lateral distance from the magnetochemical sensor.

FIG. 5 is a plane view scanning electron microscopy (SEM) image of an exemplary magnetochemical sensor with a plurality of magnetic particles.

FIGS. 6A, 6B, 6C, and 6D illustrate four example random distributions of ten magnetic particles across a surface of a detection device that includes a magnetochemical sensor.

FIGS. 7A and 7B illustrate two possible approaches to surface functionalization in accordance with some embodiments.

FIG. 8 illustrates a detection device with a functionalized surface within an adjacent trench in accordance with some embodiments.

FIGS. 9A and 9B illustrate a portion of an example detection device in accordance with some embodiments.

FIG. 10A illustrates an example of where magnetic particles might settle within a detection device that does not use the surface functionalization techniques described herein.

FIG. 10B illustrates an example of where the magnetic particles might settle within a detection device in accordance with some embodiments.

FIG. 11A illustrates a portion of another example detection device in accordance with some embodiments.

FIG. 11B illustrates the completed portion of the detection device in accordance with some embodiments.

FIG. 12A is a top view of a detection device in accordance with some embodiments.

FIGS. 12B and 12C are cross-section views of the detection device illustrated in FIG. 12A.

FIG. 13A is a top view of another example detection device in accordance with some embodiments.

FIG. 13B is a cross-section view of the detection device illustrated in FIG. 13A.

FIG. 14 is a flow diagram illustrating an example of a method of making a detection device in accordance with some embodiments.

FIG. 15 is a flow diagram illustrating another example of another method of making a detection device in accordance with some embodiments.

To facilitate understanding, identical reference numerals have been used, where possible, to designate identical elements that are common to the figures. It is contemplated that elements disclosed in one embodiment may be beneficially utilized in other embodiments without specific recitation. Moreover, the description of an element in the context of one drawing is applicable to other drawings illustrating that element.

### DETAILED DESCRIPTION

Disclosed herein are systems, devices, and methods to improve the likelihood that a magnetochemical sensor is able to detect magnetic particles coupled to molecules being detected and/or monitored. The detection probability is increased by functionalizing at least one surface within a fluid region of a detection device such that the functionalized regions (a) attract magnetic particles to locations at which they are more likely to be detected by one or more magnetochemical sensors, or (b) repel magnetic particles away from locations at which they are unlikely to be detected by one or more magnetochemical sensors, or (c) both (a) and (b). To fabricate some of the embodiments, the same mask that is used to pattern lines (also referred to herein as electrodes) allowing the magnetochemical sensors to be interrogated (e.g., read) can be used to functionalize the surface(s) of the device, thereby reducing the likelihood that the functionalized regions are misaligned with respect to the magnetochemical sensors. It is to be understood that the fluid region can, but is not required to, hold fluids. Rather, the fluid region may be dipped into a fluid (e.g., a liquid, gas, etc.).

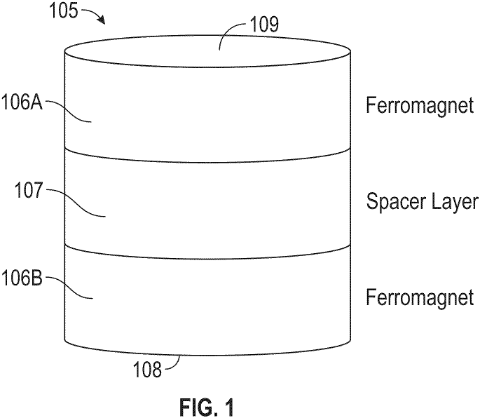

FIG. 1 illustrates a portion of a magnetochemical sensor 105 in accordance with some embodiments. The exemplary magnetochemical sensor 105 of FIG. 1 has a bottom surface 108 and a top surface 109 and comprises three layers: the ferromagnetic layer 106A, the ferromagnetic layer 106B, and a nonmagnetic spacer layer 107 situated between the ferromagnetic layer 106A and the ferromagnetic layer 106B. The nonmagnetic spacer layer 107 may be, for example, a metallic material such as, for example, copper or silver, in which case the structure is called a spin valve (SV), or it may be an insulator such as, for example, alumina or magnesium oxide, in which case the structure is referred to as a magnetic tunnel junction (MTJ). Suitable materials for use in the ferromagnetic layer 106A and the ferromagnetic layer 106B include, for example, alloys of Co, Ni, and Fe (sometimes mixed with other elements). The ferromagnetic layer 106A and the ferromagnetic layer 106B can be engineered to have their magnetic moments oriented either in the plane of the film or perpendicular to the plane of the film. Additional materials may be deposited below, above, and to the sides of the ferromagnetic layer 106A, ferromagnetic layer 106B, and nonmagnetic spacer layer 107 shown in FIG. 1 to serve purposes such as interface smoothing, texturing, and protection from processing used to pattern the device into which the magnetochemical sensor 105 is incorporated, but the active region of the magnetochemical sensor 105 lies in the tri-layer structure shown in FIG. 1.

A magnetochemical sensor 105 can detect a magnetic particle as long as the magnetic field of the magnetic particle causes a detectable change in some characteristic of the magnetochemical sensor 105 (e.g., a voltage, current, resistance, frequency, noise spectrum, etc.). As explained further below, the likelihood that the magnetic particle causes a detectable change to a characteristic of the magnetochemical sensor 105 is dependent on the distance between the magnetochemical sensor 105 and the magnetic particle.

A magnetochemical sensor 105 can use a quantum mechanical effect known as spin transfer torque. In such devices, the electrical current passing through the ferromagnetic layer 106A (or ferromagnetic layer 106B) in a SV or a MTJ preferentially allows electrons with spin parallel to the layer’s moment to transmit through, while electrons with spin antiparallel are more likely to be reflected. In this manner, the electrical current becomes spin polarized, with more electrons of one spin type than the other. This spin-polarized current then interacts with the ferromagnetic layer 106B (or ferromagnetic layer 106A), exerting a torque on the layer’s moment. This torque can in different circumstances either cause the moment of the ferromagnetic layer 106B (or ferromagnetic layer 106A) to precess around the effective magnetic field acting upon the ferromagnet, or it can cause the moment to reversibly switch between two orientations defined by a uniaxial anisotropy induced in the system. The resulting spin torque oscillators (STOs) are frequency-tunable by changing the magnetic field acting upon them. Thus, they have the capability to act as magnetic-field-to-frequency (or phase) transducers (thereby producing an AC signal having a frequency). Changes in the frequency can be detected to detect the presence or absence of magnetic particles near the magnetochemical sensor 105.

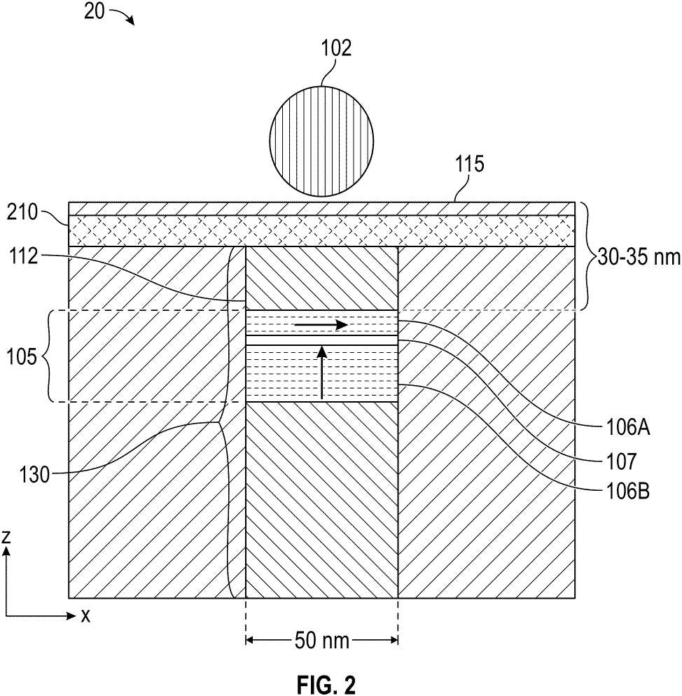

FIG. 2 illustrates the example magnetochemical sensor 105 of FIG. 1 in the context of an example sensor stack 130 of a detection device 20 with a magnetic particle 102 situated above the sensor stack 130. In the sensor stack 130, the ferromagnetic layer 106B is the pinned layer, and the ferromagnetic layer 106A is the free layer. In the example of FIG. 2, the ferromagnetic layer 106B has a fixed direction of magnetization that is perpendicular to the plane of the ferromagnetic layer 106B. The direction of magnetization of the ferromagnetic layer 106A is variable and is illustrated as being parallel to the plane of the ferromagnetic layer 106A. The nonmagnetic spacer layer 107 is situated between the ferromagnetic layer 106A and the ferromagnetic layer 106B as described above. Situated above the ferromagnetic layer 106A is a cap layer 112. The cap layer 112 may provide additional perpendicular anisotropy to the ferromagnetic layer 106A as well as protect the underlying layers during manufacture, such as during high temperature annealing. The cap layer 112 may have, for example, a Ru/Ta/Ru configuration. The sensor stack 130 may be encapsulated in an electrically insulating material as is known in the art.

A lower electrode (not shown) and an upper electrode may be positioned, respectively, near the bottom surface 108 and the top surface 109 of the magnetochemical sensor 105. FIG. 2 illustrates the electrode 210, which may be the upper electrode. The electrodes may be constructed of a non-magnetic, electrically conductive material, such as, for example, TaN, TiN, W, etc., and may provide an electrical connection with circuitry that allows the magnetochemical sensor 105 to be read. The circuitry can include, for example, a processor and other components that are well known in the art, such as a current source, etc. In operation, the processor(s) can cause a current to be applied to the electrodes (e.g., including the electrode 210) to detect a characteristic of the magnetochemical sensor 105, where the characteristic indicates the presence of at least one magnetic particle 102 or the absence of any magnetic particle 102 within range of the magnetochemical sensor 105. In other words, the characteristic (e.g., resistance, frequency, voltage, signal level, noise, etc.) indicates whether the magnetochemical sensor 105 has detected at least one magnetic particle 102 or has not detected any magnetic particle 102. The processor(s) may assess the value of the characteristic (e.g., a frequency, a wavelength, a magnetic field, a resistance, a noise level, etc.) and determine that a magnetic particle 102 was (or was not) detected based on a comparison of the value of the characteristic to a threshold (e.g., by determining whether the value of the characteristic for a magnetochemical sensor 105 meets or exceeds a threshold) or a baseline value. As another example, a processor may compare the obtained characteristic of a magnetochemical sensor 105 to a previously-detected value of the characteristic (e.g., a baseline value for the magnetochemical sensor 105) and base the determination of whether a magnetic particle 102 was or was not detected on a change in the value of the characteristic (e.g., a change in magnetic field, resistance, noise level, frequency, etc.).

FIG. 2 shows a magnetic particle 102 situated directly above the magnetochemical sensor 105. (The molecule to which the magnetic particle 102 may be attached is not illustrated.) The magnetic particle 102 is approximately 30-35 nm away from the top of the magnetochemical sensor 105 due to the presence of, for example, the cap layer 112 and/or other layers of protective material (e.g., insulator, dielectric) and the electrode 210 that assists in reading the magnetochemical sensor 105. Thus, FIG. 2 illustrates a possible, practical configuration/geometry in which a magnetochemical sensor 105 might be used to detect the presence of a magnetic particle 102.

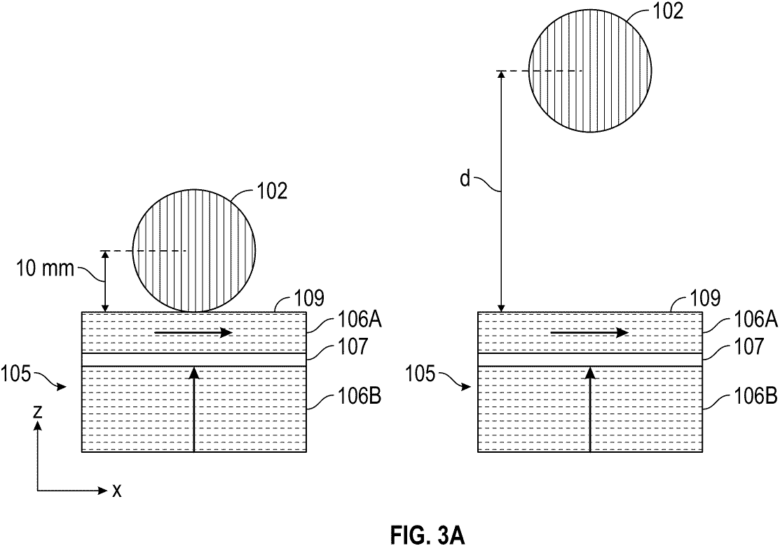

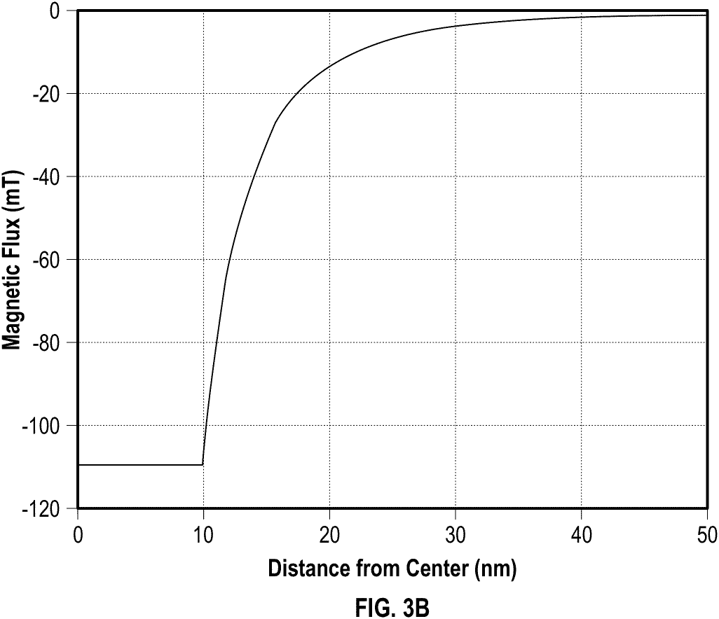

FIG. 3A illustrates a configuration of a magnetochemical sensor 105 and a magnetic particle 102 that can be used to illustrate how the detected magnetic flux density varies with the distance, d, between the magnetochemical sensor 105 and the magnetic particle 102. As shown in FIG. 3A, the magnetic particle 102 has a diameter of 20 nm. When the magnetic particle 102 is situated on top of the magnetochemical sensor 105 as shown in the left panel of FIG. 3A, the distance, d, between the upper surface of the magnetochemical sensor 105 and the center of the magnetic particle 102 is 10 nm.

FIGS. 3B and 3C illustrate how the detected magnetic flux density of the magnetic particle 102 varies with its vertical distance, d (shown in the right panel of FIG. 3A), from the top surface 109 of the magnetochemical sensor 105. Specifically, FIGS. 3B and 3C illustrate how the detected magnetic flux density changes as the magnetic particle 102 of FIG. 3A remains laterally centered over the magnetochemical sensor 105 of FIG. 3A but its center is at various distances, d, above the top surface 109. As FIG. 3B shows, the magnetic field drops rapidly as the magnetic particle 102 moves away from the magnetochemical sensor 105. FIG. 3B shows that when the magnetic particle 102 is situated on the top surface 109 of the magnetochemical sensor 105 (as shown in the left panel of FIG. 3A), the surface flux density is about 110 mT, but the flux density degrades rapidly as the distance, d, between the top surface 109 and the center of the magnetic particle 102 increases. For example, when the value of d shown in the right panel of FIG. 3A is only 10 nm (meaning that the center of the magnetic particle 102 is 20 nm from the top surface 109), the magnetic field is only about 14 mT. FIG. 3C is a magnified view of the portion of FIG. 3B showing the surface flux density for distances of 20 to 50 nm between the center of the magnetic particle 102 and the top surface 109. FIG. 3C indicates that when the center of the magnetic particle 102 is at a distance of 40 to 45 nm above the top surface 109, as it would be in the example configuration shown in FIG. 2, the magnetic field is only 1-2 mT as compared to 110 mT when the magnetic particle 102 is on the top surface 109. As described further below, although a field of 1-2 mT is detectable using the magnetochemical sensor 105 described above, to improve the likelihood of detection in a practical system, FIGS. 3B and 3C indicate that it is desirable for the magnetic particle 102 to be much closer to the magnetochemical sensor 105 than when its center is 40-45 nm above its top surface 109.

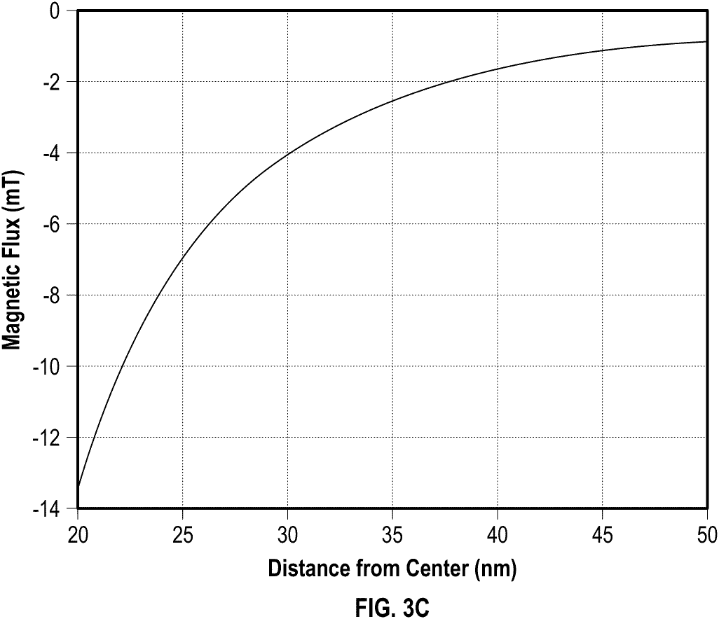

FIG. 4 is another illustration to illustrate how the detected magnetic field caused by the magnetic particle 102 changes with both vertical distance and lateral distance from the magnetochemical sensor 105. Specifically, FIG. 4 illustrates the results of nanomagnetic simulations of an exemplary magnetochemical sensor 105 in the presence of a magnetic particle 102 at various lateral and vertical positions relative to the top surface 109 of the magnetochemical sensor 105 in accordance with some embodiments. The contour plot 160 illustrates the magnetic field acting on the magnetochemical sensor 105 for various lateral positions of the magnetic particle 102 in the x-y plane when the center of the magnetic particle 102 is 10 nm above the x-y plane (at a z value of 10 nm). As indicated by the cross section 162, the magnetic sensor 105 is centered at coordinates (0, 0) in the x-y plane, indicated as position 164. The cross section 162 shows the magnetic field magnitude as a function of the lateral position of the magnetic particle 102 along the x-axis at a position of y = 0 (indicated by the dashed line 174 in the contour plot 160) and at various positions along the z-axis, ranging from 10 nm to 60 nm away from the surface (e.g., top surface 109) of the magnetochemical sensor 105. The plot 170 shows the magnetic field magnitude along the dashed line 168 in the cross section 162. As shown, when the center of the magnetic particle 102 is 10 nm directly above the magnetochemical sensor 105, the magnetic field magnitude is approximately 100 Oersted, and when the magnetic particle 102 is 60 nm above the magnetochemical sensor 105, the magnetic field magnitude is near 0.

The cross section 172 shows the magnetic field magnitude as a function of the lateral position of the magnetic particle 102 along the y-axis at a position of x = 0 (indicated by the dashed line 166 of the contour plot 160) and at various positions along the z-axis, ranging from 10 nm to 60 nm away from the surface (e.g., the top surface 109) of the magnetochemical sensor 105. The plot 176 shows the magnetic field magnitude along the dashed line 178 in the cross section 172, at the position 180 shown in contour plot 160, which is at a lateral offset of 39 nm along the y-axis. As shown, when the center of the magnetic particle 102 is 10 nm above the surface of the magnetochemical sensor 105 and laterally offset by 39 nm, the magnetic field magnitude is approximately -4 Oersted, and when the magnetic particle 102 is 60 nm above the magnetochemical sensor 105 and laterally offset by 39 nm, the magnetic field magnitude is near 0.

Thus, FIGS. 3B, 3C, and 4 illustrate that the magnitude of the magnetic field is strongly dependent on the position of the magnetic particle 102 relative to the magnetochemical sensor 105 and the distance between the magnetic particle 102 and the magnetochemical sensor 105. The detected magnitude changes substantially as the magnetic particle 102 changes position in three-dimensional space. Even slight changes in position cause significant changes in the detected magnetic field. Taken together, FIGS. 3B, 3C, and 4 indicate that the magnetic particle 102 is more likely to be detected when it is closer to the magnetochemical sensor 105 than when it is further away.

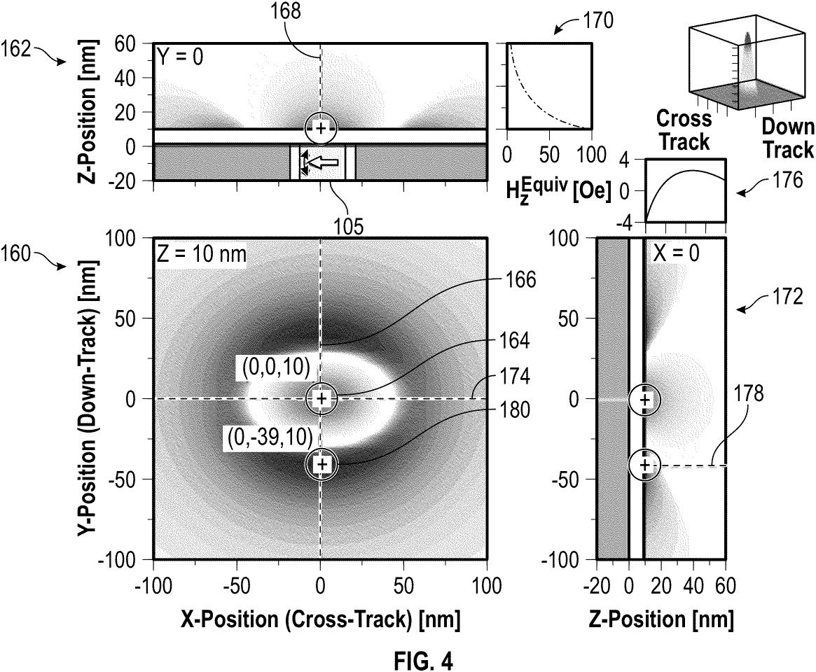

In conventional systems, magnetic particles 102 tend to settle randomly on the surface of a detection device. To illustrate, FIG. 5 is a plane view scanning electron microscopy (SEM) image of an exemplary magnetochemical sensor 105 that is an MTJ with a diameter in the x-y plane of approximately 40 nm² with a plurality of magnetic particles 102 present (appearing as white dots). In FIG. 5, the junction area is parallel to the x-y plane (out of the page), and the tunneling current flows in the z-axis direction. As shown by the SEM image of FIG. 5, the magnetic particles 102 tend to be distributed randomly across the surface of the detection device in which the magnetochemical sensor 105 is situated. As a result, it is unlikely that any magnetic particle 102 happens to be close enough to the magnetochemical sensor 105 to be detected successfully or reliably.

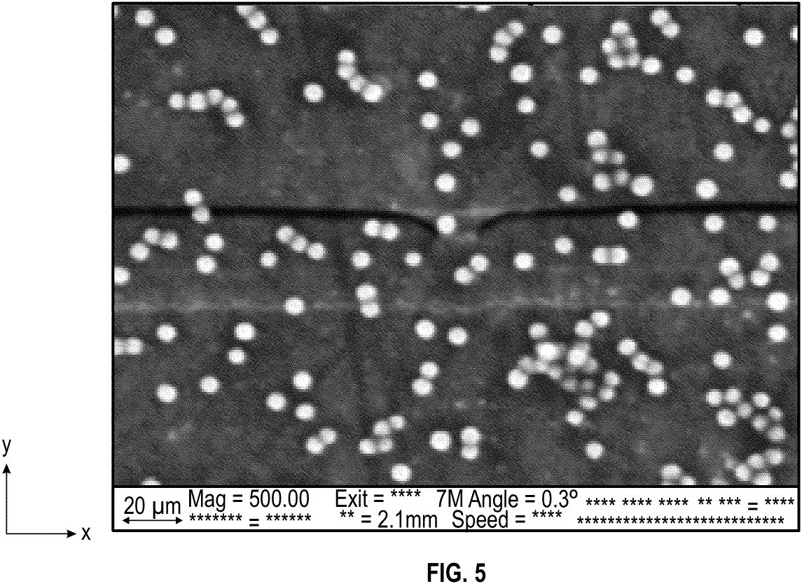

For example, FIGS. 6A, 6B, 6C, and 6D illustrate four example random distributions of ten magnetic particles 102 across an approximately 200 nm x 200 nm surface of a detection device that includes a magnetochemical sensor 105, shown at a position of (100 nm, 100 nm). With the same assumptions made above in the discussions of FIGS. 3B, 3C, and 4, despite a relatively high density of magnetic particles 102 over the surface of the detection device, only the distribution shown in FIG. 6C would be likely to result in a positive detection, assuming the center of the magnetochemical sensor 105 is at the coordinates (100 nm, 100 nm). Because an objective is for the magnetochemical sensor 105 to detect the presence of a single magnetic particle 102, it would be desirable to increase the likelihood that a magnetic particle 102 is situated directly over the magnetochemical sensor 105.

One possible approach to attract the magnetic particle 102 to the area in a detection device that is closest to the magnetochemical sensor 105 is to functionalize the surface 115 of the detection device that is directly over the magnetochemical sensor 105 using a suitable chemistry. Surface functionalization allows the surface properties of a material or device to be modified. As an example, thiols are compounds that have an -SH functional group. Because of the strong affinity of sulfur with metals, thiol moieties can be used as end groups when a surface to be modified is a noble metal (e.g., gold). For example, the thiol moieties can be used to form a strong Au-S bond. A wide variety of other metals, such as silver (Ag), can also be used as the substrate.

A variety of compounds can be used for surface functionalization. These compounds include, for example, hydrophobic octadecanethiol or mercaptoundecanoic acid, which is hydrophilic. Phosphine derivatives, which bond strongly to Au, are also suitable for surface functionalization. Other examples are amines, pyridine, and carboxylates, disulphide, dithiocarbamates, trithiols, mercaptopyridines, mercaptothiadizoles, or lipoic acid derivatives. Additional details can be found in “Functionalization of Gold Nanoparticles by Inorganic Entities” by Frédéric Dumur, Eddy Dumas, and Cédric R. Mayer, Nanomaterials 2020, 10, 548; (doi:10.3390/nano10030548), the entirety of which is hereby incorporated by reference for all purposes.

Once a surface has been functionalized, molecules can be attached to the surface. For example, in applications involving DNA or RNA (e.g., for sequencing, detection, nucleic acid data storage, etc.), suitably modified nucleic acid molecules (e.g., after thiolation) can be grafted directly onto the functionalized region of the surface. Alternative or additional molecules can also be grafted on top of the functionalized zones.

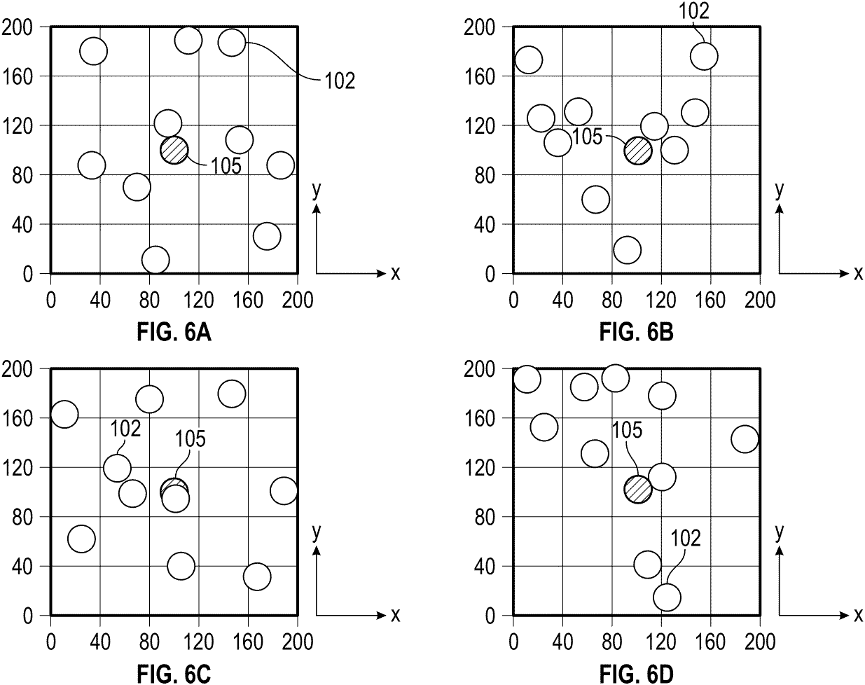

FIGS. 7A and 7B illustrate two possible approaches to surface functionalization in accordance with some embodiments. In FIG. 7A, a functionalized surface 116 on the surface of the detection device that is directly over a magnetochemical sensor 105 is functionalized to attract the magnetic particle 102 to the functionalized surface 116 above the magnetochemical sensor 105. In FIG. 7B, the surface of the detection device excluding the area directly over the magnetochemical sensor 105 is functionalized to repel the magnetic particle 102 away from the non-sensitive areas so that the magnetic particles 102 will tend to settle over the magnetochemical sensor 105. FIG. 7B illustrates that the region 117A and the region 117B have been functionalized to repel the magnetic particle 102 so that it is more likely to settle in the area directly above the magnetochemical sensor 105. Although FIGS. 7A and 7B show only a single magnetochemical sensor 105, it is to be appreciated that an implemented system can include any number of magnetochemical sensors 105, which may be substantially identical to each other. It is also to be appreciated that the approaches shown in FIGS. 7A and 7B can be used together such that some regions (e.g., functionalized surface(s) 116) are functionalized to attract the magnetic particle 102, and other regions (e.g., region 117A, region 117B) are functionalized to repel the magnetic particle 102. It is to be appreciated that embodiments can include two or more of (a) at least one region functionalized to attract the magnetic particle 102, (b) at least one region functionalized to repel the magnetic particle 102, (c) at least one non-functionalized (e.g., untreated) region.

The embodiments illustrated in FIGS. 7A and 7B are configured draw the magnetic particles 102 to positions in which they can be detected successfully by the magnetochemical sensors 105. These approaches may be difficult to implement for several reasons, however. First, as discussed above, the ability of the magnetochemical sensor 105 to detect a magnetic particle 102 is strongly dependent on the position of the magnetic particle 102 relative to the magnetochemical sensor 105, and the detected magnitude of the magnetic field associated with the magnetic particle 102 is dependent on the distance between the magnetic particle 102 and the magnetochemical sensor 105. As explained above, an implementation may include many magnetochemical sensors 105 (e.g., thousands, tens of thousands, or more), which may be situated in an array (e.g., having rows and columns). Consequently, in order to functionalize the surface of a detection device so that the only areas in which the magnetic particles 102 settle is directly above the magnetochemical sensors 105, a precise alignment is needed to selectively pattern only the areas of the detection device directly above the magnetochemical sensors 105 (or, conversely, all areas except those directly above the magnetochemical sensors 105), which translates to a substantial cost in masks and lithography. Second, typical subtractive processes used in the manufacturing of the detection device (e.g., etching, milling, etc.) are not well-suited for patterning surface functionalizations because the mask material and/or chemicals used in these processes can change the surface chemistry. Third, the size of the area over the magnetochemical sensor 105 is nanometer-sized, and lift-off techniques will likely interfere with the surface chemistry. Thus, it may be difficult to implement the embodiments illustrated in FIGS. 7A and 7B.

Although a configuration in which the magnetochemical sensor 105 is “buried” (e.g., as shown in FIG. 2) may be convenient, it may not be ideal for detection of magnetic particles 102 for the reasons discussed above. For example, as shown in FIGS. 3B, 3C, and 4, in this geometry and under the assumed conditions described above, only a single-digit percentage of the magnetic field can be expected to reach the magnetochemical sensor 105.

Because the likelihood of successful detection of a magnetic particle 102 is dependent on the distance between the magnetic particle 102 and the magnetochemical sensor 105, another option to improve the detection likelihood is to change the sensor geometry in order to bring the magnetic particle 102 closer to the magnetochemical sensor 105. For example, an alternative approach to draw the magnetic particle 102 closer to the magnetochemical sensor 105 is to create a trench to the side of the magnetochemical sensor 105 and to functionalize the sidewall of the trench, near the magnetochemical sensor 105, either to attract the magnetic particle 102 to the sensitive area of the magnetochemical sensor 105 (e.g., as described above in the discussion of FIG. 7A) or to repel the magnetic particle 102 from the non-sensitive areas of the sidewall (e.g., as described above in the discussion of FIG. 7B). As a result, the magnetic particle 102 should settle in a position that is closer to the sensitive area of the magnetochemical sensor 105.

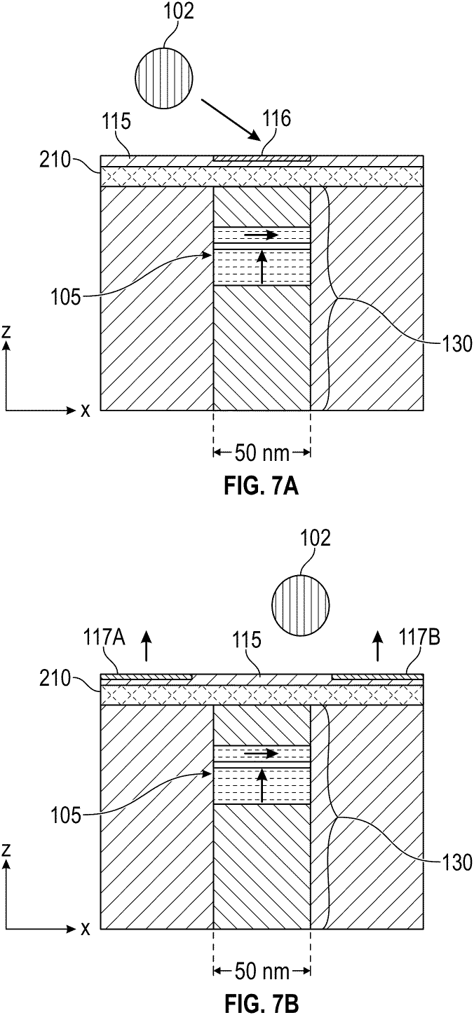

FIG. 8 illustrates such an approach. A trench 185 created to the side of the magnetochemical sensor 105 includes a sidewall 190. In the example of FIG. 8, a region 192 of the sidewall 190 is functionalized to attract the magnetic particle 102. (As noted above, the portions of the sidewall 190 that do not include the region 192 could alternatively or additionally be functionalized to repel the magnetic particle 102.) Accordingly, the approach shown in FIG. 8 should improve the likelihood that (a) a magnetic particle 102 is situated near the magnetochemical sensor 105 and (b) the magnetochemical sensor 105 detects that magnetic particle 102.

One disadvantage of the approach shown in FIG. 8, however, is that patterning the sidewall 190 to create the region 192 (and/or to create functionalized, repelling regions other than the region 192) may be difficult and may require steps and/or processes in addition to those typically used to manufacture thin-film devices. Accordingly, it may be impractical or economically infeasible to create a detection device that includes the geometry and functionalization shown in FIG. 8.

Accordingly, disclosed herein are detection devices and systems that provide improved capabilities to detect magnetic particles 102 and methods of making the detection devices and systems that do not require costly lithography that might not be compatible with surface functionalization chemistry. In some embodiments, the manufacturing process includes at least one self-aligned surface modification step that incorporates a chemical compound. The at least one self-aligned surface modification step is relatively simple and allows the detection device to be accurately patterned (functionalized) during fabrication of the detection device without requiring additional masks.

As explained above in the discussion of FIGS. 7A and 7B, the surface of a detection device can be functionalized to attract magnetic particles 102 (and/or to repel magnetic particles 102), but, at the scales involved, it can be difficult or impossible to create the functionalized regions with the desired precision. The inventors had the insight that surface functionalization providing adequate precision can be performed during fabrication and without the need for additional lithography masks. Specifically, for a geometry similar to that shown in FIGS. 7A and 7B, the inventors recognized that after depositing the material for the top electrode used to read the magnetochemical sensor 105, and while the mask used to pattern the electrode remains in place, a thin reactive layer (e.g., gold) can be added to the electrode. A functionalization step can then be performed to functionalize the surface of the reactive layer. Because the reactive layer is added during/after electrode fabrication, while the mask used to deposit the electrode material remains in place, the reactive layer and the electrode have substantially identical layouts (subject to manufacturing tolerances). As a result, the alignment of the functionalized region relative to the magnetochemical sensor 105 is as precise as the electrode placement, and, assuming the electrode is properly aligned with (e.g., situated over) the magnetochemical sensor 105, so is the functionalized region. Although the result of this process is that a region the size of the entire top electrode (and thus an area larger than the sensitive region reliably detected by the magnetochemical sensor 105) is functionalized to attract the magnetic particles 102, the approach still provides a strong localization effect on the magnetic nanoparticles, as explained further below.

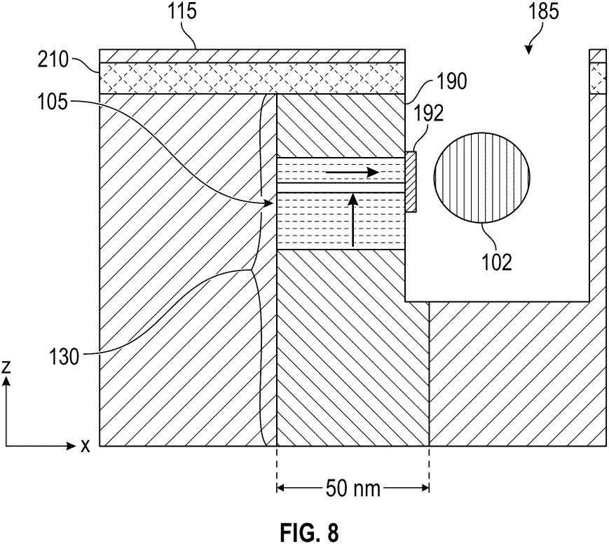

FIGS. 9A and 9B illustrate a portion of an example detection device 100A in accordance with some embodiments. FIG. 9A is a cross-sectional view (in the x-z plane) of the portion of the detection device 100A, and FIG. 9B is a top view (in the x-y plane), showing the surface 115 of the detection device 100A. The surface 115 may be situated, for example, in a fluid region of the detection device 100A that holds fluids containing molecules to be detected and magnetic particles 102. As illustrated, a reactive layer 216, which has substantially the same layout as the electrode 210 over the magnetochemical sensor 105, is added to (e.g., on top of) the electrode 210 during the fabrication process. The electrode 210 may be, for example, one of two electrodes used to read the magnetochemical sensor 105. For example, it may be a top electrode. The reactive layer 216 may comprise any suitable material, such as, for example, one or more of ruthenium (Ru), rhodium (Rh), palladium (Pd), silver (Ag), osmium (Os), iridium (Ir), platinum (Pt), or gold (Ag). The reactive layer 216 may have a thickness of, for example, approximately 1 nm. As shown in FIG. 9B, in the illustrated embodiment, the region that is functionalized to attract the magnetic particles 102 covers the entire electrode 210.

Accordingly, FIGS. 9A and 9B illustrate a detection device 100A that comprises a magnetochemical sensor 105 for detecting magnetic particles 102, an electrode 210 coupled to the magnetochemical sensor 105, and a reactive layer 216 situated on the electrode 210 and forming part of a surface of a fluid region of the detection device 100A. The reactive layer 216 and the electrode 210 are situated over the magnetochemical sensor 105. A surface of the reactive layer 216 is functionalized to attract magnetic particles 102, and/or another surface of the detection device 100A that excludes the surface of the reactive layer 216 is functionalized to repel the magnetic particles 102. The reactive layer 216 may comprise any suitable material, such as, for example, one or more of ruthenium (Ru), rhodium (Rh), palladium (Pd), silver (Ag), osmium (Os), iridium (Ir), platinum (Pt), or gold (Ag). The reactive layer 216 may have a thickness of, for example, approximately 1 nm.

In the illustrated embodiment of FIGS. 9A and 9B, the layout of the reactive layer 216 is substantially identical to the layout of at least a portion of the electrode 210 (because the same mask is used to patten both).

FIGS. 9A and 9B illustrate the reactive layer 216 situated above the magnetochemical sensor 105. It is to be understood that the reactive layer 216 and the associated fluid region could alternatively be under the magnetochemical sensor 105. Moreover, a detection device 100A may include a first reactive layer 216 over the magnetochemical sensor 105 and a second reactive layer 216 under the magnetochemical sensor 105 (e.g., to increase the likelihood of a magnetic particle 102 being drawn close enough to the magnetochemical sensor 105 to be detected).

As described above, the magnetochemical sensor 105 can comprise a ferromagnetic layer 106A, a ferromagnetic layer 106B, and a 107 situated between and coupled to the ferromagnetic layer 106A and the ferromagnetic layer 106B. The magnetochemical sensor 105 may be, for example, an MR sensor.

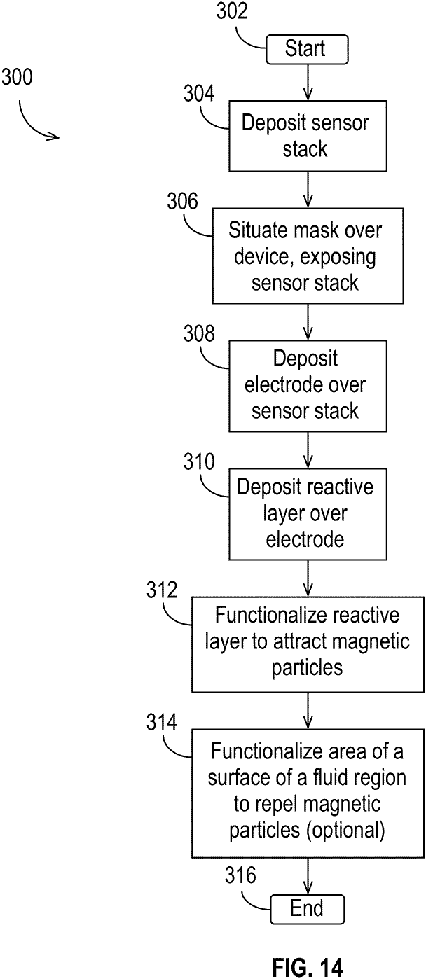

As described further below in the discussion of FIG. 14, the detection device 100A can be fabricated from a wafer using a photolithography process comprising two fundamental steps of: (a) covering a portion of a surface of the wafer, and (b) removing substrate material from the exposed (not covered) surface of the wafer. Step (a) may be accomplished, for example, using a binary mask having hard edges to create a well-defined pattern in a photoresist layer that is applied to the wafer surface. Step (b) may be accomplished, for example, by lapping, etching, or milling (e.g., using an ion beam) to transfer the photoresist pattern to the wafer surface. The steps (a) and (b) can be repeated multiple times to create the layers of the detection device 100A (e.g., ferromagnetic layer 106A, ferromagnetic layer 106B, nonmagnetic spacer layer 107, cap layer 112, electrode 210, reactive layer 216).

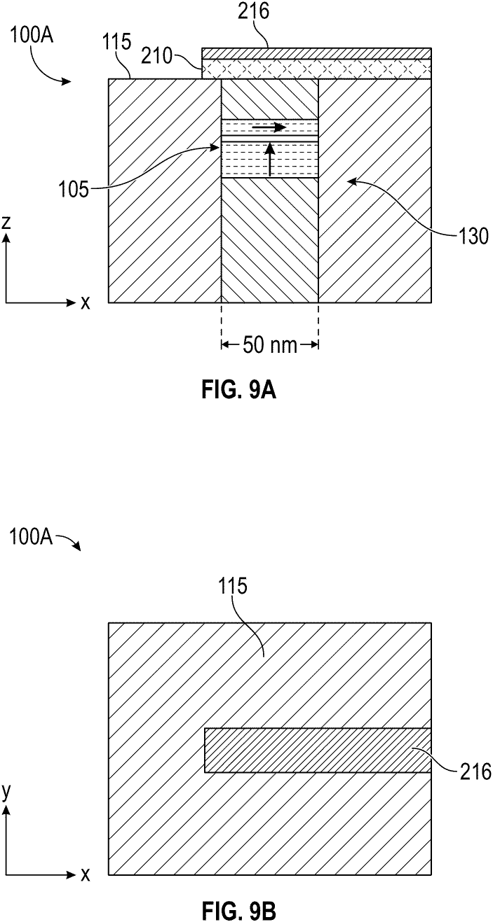

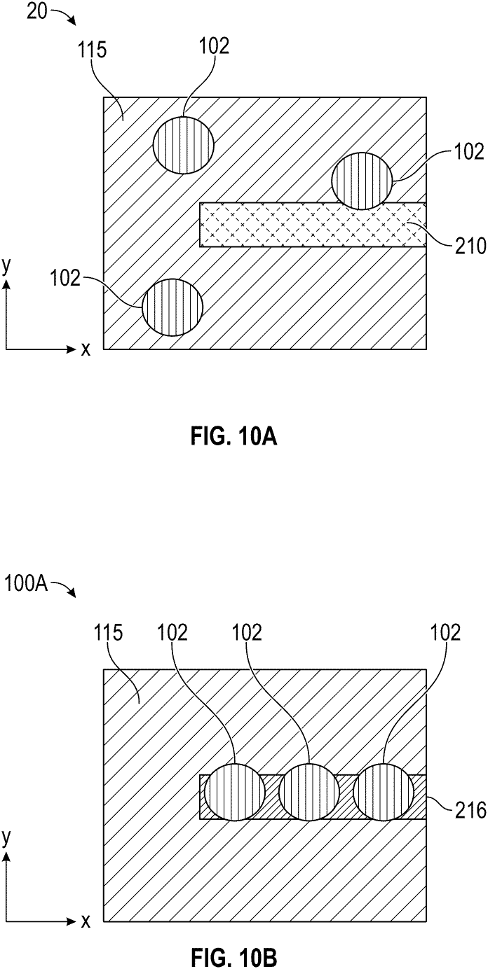

FIGS. 10A and 10B illustrate how the example embodiment of FIGS. 9A and 9B can improve the likelihood of detecting a magnetic particle 102. FIG. 10A illustrates an example of the locations at which magnetic particles 102 might settle within a detection device 20 that does not use the surface functionalization techniques described herein. As shown, the magnetic particles 102 settle in random locations on the surface 115 of the detection device 20, and it is unlikely that any of them would be detected by a magnetochemical sensor 105 under the electrode 210 because of their distances from the magnetochemical sensor 105.

FIG. 10B illustrates an example of the locations at which the magnetic particles 102 might settle within a detection device 100A, which includes the reactive layer 216 that has been functionalized. As shown, because the surface 115 of detection device 100A over the electrode 210 has been functionalized (using the reactive layer 216), the magnetic particles 102 settle over the electrode 210. Although some of the magnetic particles 102 will still be too far away from the magnetochemical sensor 105 to be detected, the likelihood that at least one magnetic particle 102 is close enough to be detected by the magnetochemical sensor 105 is significantly higher with the configuration of FIG. 10B than with the configuration of FIG. 10A. In FIG. 10B, the magnetic particles 102 are concentrated in an area that is approximately 90% smaller than in FIG. 10A, which translates to an increase in the likelihood of detection.

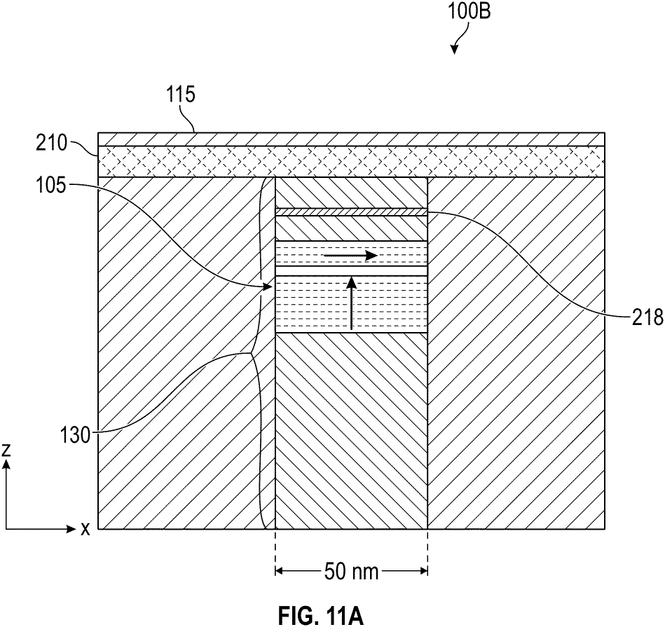

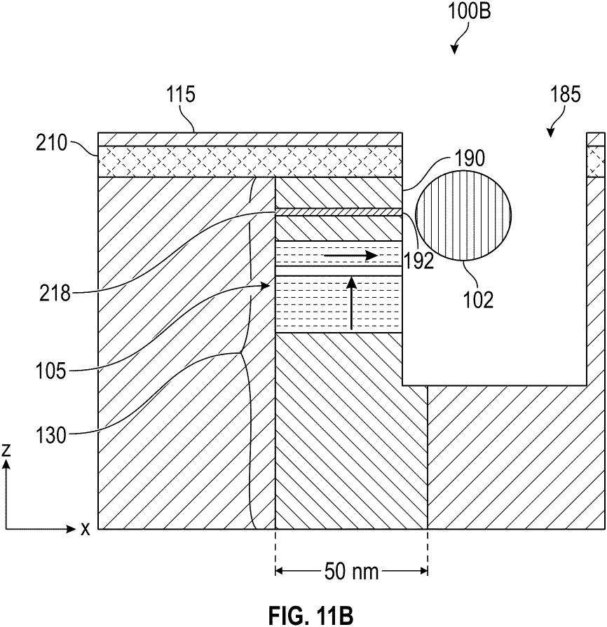

The techniques disclosed herein can also be used to address the drawbacks of the approach illustrated in FIG. 8. FIG. 11A is a cross-sectional view (in the x-z plane) of a portion of another example detection device 100B during the fabrication process in accordance with some embodiments. As illustrated, a reactive layer 218 is integrated into the stack that includes the magnetochemical sensor 105. The reactive layer 218 may be similar to the reactive layer 216 described above. For example, the reactive layer 218 may have a thickness of around 1 nm, and it may comprise any suitable material (e.g., gold, silver, etc.). Because the reactive layer 218 material has high mobility, it may be advantageous to deposit the reactive layer 218 before the top lead deposition, but after the anneal of the magnetic stack, which should have no adverse effect on the magnetic properties of the magnetochemical sensor 105. The magnetic stack of the detection device 100B can be fabricated as described above in the discussion of FIGS. 10A and 10B and described further below in the discussion of FIG. 4 (e.g., from a wafer using a photolithography process comprising two fundamental steps of (a) covering a portion of a surface of the wafer, and (b) removing substrate material from the exposed (not covered) surface of the wafer).

The magnetochemical sensor 105 shown in the detection device 100B may be, for example, a modified version of a configuration that could be a part of a magneto-resistive random access memory (MRAM) stack, with the modification including the reactive layer 218 being incorporated. For example, a Ru/Ta/Ru stack (e.g., in a cap layer 112) could be replaced by a Ru/Ta/Au/Ru stack or a Ru/Ta/Ag/Ru stack. It will be appreciated by those having ordinary skill in the art that other approaches are possible and are within the scope of the disclosures herein.

FIG. 11B shows a cross-sectional view (in the x-z plane) of a portion of the detection device 100B after additional fabrication steps have been performed in accordance with some embodiments. A trench 185 is created to expose the reactive layer 218. The creation of the trench 185 can be accomplished using well-known, conventional techniques, such as, for example, applying photoresist material or a hard mask over the portions of the detection device 100B that are not to be removed. The mask does not protect the portion of the surface 115 to the side of the magnetochemical sensor 105, which is the region in which the trench 185 will be created. The material residing where the trench 185 will be can be removed using any suitable method known to those of skill in the art. For example, the material residing in the trench 185 region can be removed using well-known, conventional techniques, such as, for example, ion-milling or etching.

The photoresist material or hard mask can be any conventional material that protects the portion of the portion of the detection device 100B that includes the magnetochemical sensor 105 while the trench 185 is being removed (e.g., by etching or ion milling). Other well-known techniques to lithographically define a region of the detection device 100B to be protected during a subsequent fabrication step could also be used in addition or instead.

After creation of the trench 185, the exposed reactive layer 218 can then be functionalized to create a functionalized region 192 as described above to attract the magnetic particle 102. If complete encapsulation of the magnetochemical sensor 105 is desired, the chemically functionalized areas can also be used to control a conformal coating, for example, atomic layer deposition (ALD) can be controlled so as not to coat the functionalized region(s).

As explained above, surface functionalization can also, or alternatively, be used to repel magnetic particles 102. For example, the exposed reactive layer 218 can be functionalized with a strong hydrophile, such as mercaptoundecanoic acid. A conformal coating step can be included to coat all non-functionalized areas with a strongly hydrophobic compound, such as, for example, tridecafluoro-1, 1, 2, 2-tetrahydrooctylmethylbis(dimethylamino)silane (FOMB(DMA)S, C₈F₁₃H₄(CH₃)Si(N(CH₃)₂)₂), as described in “Conformal hydrophobic coatings prepared using atomic layer deposition seed layers and non-chlorinated hydrophobic precursors” by Cari F. Herrmann et al., J. Micromech. Microeng. 15 (2005) 1-9, which is hereby incorporated by reference in its entirety for all purposes.

Thus, FIGS. 11A and 11B illustrate an example detection device 100B that comprises a sensor stack 130 that includes a ferromagnetic layer 106A, a ferromagnetic layer 106B, a nonmagnetic spacer layer 107 situated between ferromagnetic layer 106A and the ferromagnetic layer 106B, and a reactive layer 218. The reactive layer 218 may be situated, for example, in a cap layer 112 of the sensor stack 130. The cap layer 112 may comprise a first metal layer (e.g., ruthenium (Ru)), a second metal layer (e.g., Ru), a third metal layer (e.g., tantalum (Ta)), and the reactive layer 218, where the third metal layer and the reactive layer 218 are situated between the first and second metal layers. As explained above, the reactive layer 218 may comprise any suitable material, such as, for example, one or more of ruthenium (Ru), rhodium (Rh), palladium (Pd), silver (Ag), osmium (Os), iridium (Ir), platinum (Pt), or gold (Ag). The reactive layer 218 may have a thickness of, for example, approximately 1 nm.

The detection device 100B also has trench 185 adjacent to the sensor stack 130 and exposing a surface of the reactive layer 218. A surface within the trench 185 is functionalized to direct magnetic particles 102 toward the sensor stack 130. For example, the exposed surface of the reactive layer 218 may be functionalized to attract magnetic particles 102. There may be multiple functionalized zones within the trench 185. For example, if a first zone includes the exposed surface of the reactive layer 218, a second zone that excludes the first zone (e.g., above and/or below and/or laterally displaced from the reactive layer 218) can be functionalized to repel magnetic particles 102.

The example detection device 100B of FIGS. 11A and 11B also includes an electrode 210. The reactive layer 218 is situated between the sensor stack 130 and the electrode 210.

FIGS. 11A and 11B illustrate the reactive layer 218 situated above the magnetochemical sensor 105. It is to be understood that the reactive layer 218 could alternatively be situated under the magnetochemical sensor 105. Placement of the reactive layer 218 over the magnetochemical sensor 105 may simplify fabrication of the detection device 100B because the reactive layer 218 is added after annealing the magnetochemical sensor 105 (thereby reducing the potential for material from the reactive layer 218 to diffuse into the sensor stack 130). Nevertheless, it is contemplated that the reactive layer 218 could be situated under the magnetochemical sensor 105. Moreover, it is possible for an embodiment to include multiple reactive layers 218 with surfaces exposed within the trench 185. For example, an embodiment may include a first reactive layer 218 below the magnetochemical sensor 105 and a second reactive layer 218 over the magnetochemical sensor 105. The exposed surfaces of both reactive layers 218 may be functionalized to attract magnetic particles 102. As described previously, there may be multiple functionalized zones within the trench 185, including one or more zones (e.g., above and/or below and/or laterally displaced from the reactive layer(s) 218) that are functionalized to repel magnetic particles 102.

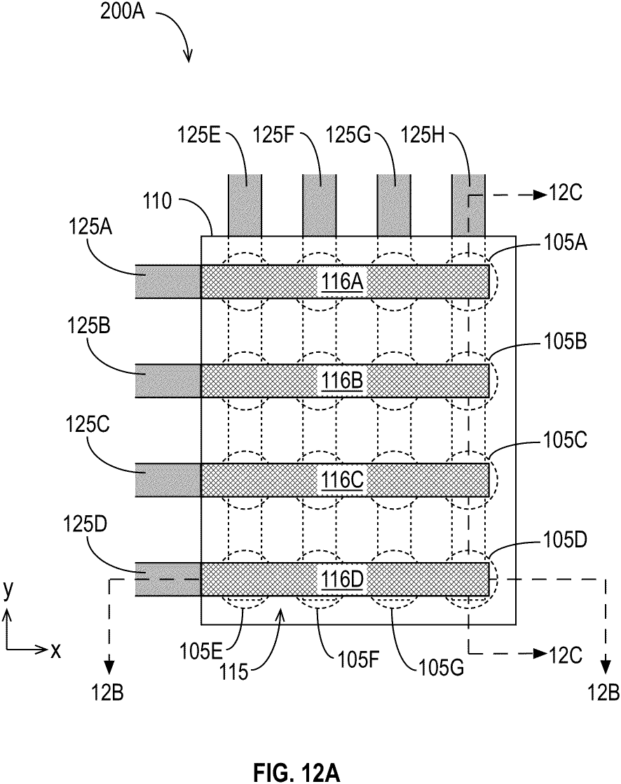

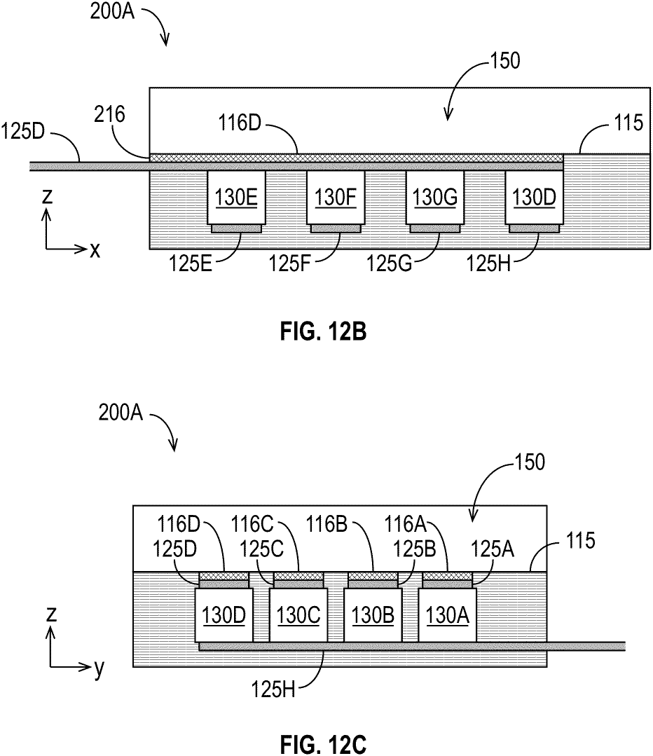

FIGS. 12A, 12B, and 12C illustrate portions of an example of a detection device 200A that includes a sensor array 110 comprising magnetochemical sensors 105 in accordance with some embodiments. FIG. 12A is a top view of the detection device 200A (in the plane arbitrarily designated as the x-y plane). As shown in FIG. 12A, the sensor array 110 includes a plurality of magnetochemical sensors 105, with sixteen magnetochemical sensors 105 shown in the sensor array 110 of FIG. 12A. In some embodiments, the magnetochemical sensors 105 in the sensor array 110 are magnetoresistive (MR) sensors that can detect, for example, a magnetic field or a resistance, a change in magnetic field or a change in resistance, or a noise level. In some embodiments, each of the magnetochemical sensors 105 of the sensor array 110 is a thin film device that uses the MR effect to detect magnetic particles 102. The magnetochemical sensors 105 may operate as potentiometers with a resistance that varies as the strength and/or direction of the sensed magnetic field changes. In some embodiments, the magnetochemical sensors 105 comprise a magnetic oscillator (e.g., a spin-torque oscillator (STO)), and the characteristic that indicates whether at least one label is detected is a frequency of a signal associated with or generated by the magnetic oscillator, or a change in the frequency of the signal.

It is to be appreciated that an implementation of a detection device 200A may include any number of magnetochemical sensors 105 (e.g., hundreds, thousands, etc. of magnetochemical sensors 105). To avoid obscuring the drawing, only seven of the magnetochemical sensors 105 are labeled in FIG. 12A, namely the magnetochemical sensors 105A, 105B, 105C, 105D, 105E, 105F, and 105G. As explained above, the magnetochemical sensors 105 detect the presence or absence of magnetic particles 102. In other words, each of the magnetochemical sensors 105 detects whether there is at least one magnetic particle 102 in its vicinity.

Each magnetochemical sensor 105 is illustrated in FIG. 12A as having a round shape in the x-y plane. It is to be understood, however, that in general the magnetochemical sensors 105 can have any suitable shape. For example, the magnetochemical sensors 105 may be cylindrical, cuboid, or any other shape in three dimensions. Moreover, different magnetochemical sensors 105 can have different shapes (e.g., some may be cuboid and others cylindrical, etc.). It is to be appreciated that the drawings are merely exemplary.

FIG. 12B is a cross-section view (in the x-z plane) of the detection device 200A at the position indicated by the long-dash line labeled “12B” in FIG. 12A, and FIG. 12C is a cross-section view (in the y-z plane) of the detection device 200A at the position indicated by the long-dash line labeled “12C” in FIG. 12A. FIGS. 12B and 12C label only the individual sensor stacks, namely the sensor stack 130A, the sensor stack 130B, the sensor stack 130C, the sensor stack 130D, the sensor stack 130E, the sensor stack 130F, and the sensor stack 130G. It is to be understood that, as described above, each of the sensor stacks 130 includes a magnetochemical sensor 105. The sensor stacks 130 of the detection device 200A are surrounded by a material that may be, e.g., an electrically-insulating material.

As shown in FIGS. 12B and 12C, the detection device 200A includes a fluid region 150. The fluid region 150 is configured to hold fluids containing molecules being detected or monitored and the magnetic particles 102. The fluid region 150 has a surface 115. The surface 115 may comprise a plurality of materials. For example, a portion of the surface 115 may be the reactive layer 216, and another portion of the surface 115 may be another material (e.g., an insulator). Thus, the surface 115 may comprise a plurality of non-intersecting regions of materials (or mixtures of materials). For example, the surface 115 may include one or more of organic polymer, metal, insulator, or a silicate. The surface 115 may include, for example, a metal oxide, silicon dioxide, polypropylene, gold, glass, or silicon.

It is to be understood that, as described above, different areas of the surface 115 can be functionalized differently. For example, some areas (e.g., the reactive layer 216) can be functionalized to attract magnetic particles 102, and other areas (e.g., some or all of the surface 115 excluding the reactive layer 216) can be functionalized to repel magnetic particles 102. In some embodiments, at least one portion of the surface 115 is functionalized as described above (e.g., to attract or repel magnetic particles 102). In the example detection device 200A shown in FIGS. 12A, 12B, and 12C, the surface 115 includes four functionalized surfaces: the functionalized surface 116A, the functionalized surface 116B, the functionalized surface 116C, and the functionalized surface 116D.

The thickness of the surface 115 may be selected so that the magnetochemical sensors 105 can detect magnetic particles 102 on the functionalized surface(s) 116 within the fluid region 150. In some embodiments, each magnetochemical sensor 105 is no more than approximately 35 nm from the nearest functionalized surface(s) 116. It is to be understood that these values are merely exemplary. It will be appreciated that an implementation of a detection device 200A may have different dimensions, and that the magnetochemical sensors 105 can be closer to or further away from the functionalized surface(s) 116.

FIGS. 12B and 12C illustrate an enclosed fluid region 150 with a top portion that extends in the x-y plane, but there is no requirement for the fluid region 150 to be enclosed. In some embodiments, the surface of the fluid region 150 has properties and characteristics that protect the magnetochemical sensors 105 from whatever fluids are in the fluid region 150, while still allowing the magnetochemical sensors 105 to detect magnetic particles 102 that are nearby (e.g., on one of the functionalized surfaces 116). Similarly, although FIGS. 12A, 12B, and 12C illustrate the fluid region 150 situated over the sensor array 110, as explained in the discussion of FIGS. 9A and 9B, the fluid region 150 may alternatively or additionally be situated below the sensor array 110.

As shown in FIGS. 12A, 12B, and 12C, the example detection device 200A includes a number of lines 125, which can perform the functions of the electrodes described above (e.g., the electrode 210). In some embodiments, each of the plurality of magnetochemical sensors 105 is coupled to at least one line 125. In the example shown in FIGS. 12A, 12B, and 12C, the detection device 200A includes the line 125A, the line 125B, the line 125C, the line 125D, the line 125E, the line 125F, the line 125G, and the line 125H. (For simplicity, this document refers generally to the lines by the reference number 125. Individual lines are given the reference number 125 followed by a letter.) Pairs of lines 125 can be used to access (e.g., interrogate) individual magnetochemical sensors 105 in the sensor array 110. In the exemplary embodiment shown in FIGS. 12A, 12B, and 12C, each magnetochemical sensor 105 of the sensor array 110 is coupled to, and can be read via, two lines 125. For example, the magnetochemical sensor 105A is coupled to the line 125A and line 125H; the magnetochemical sensor 105B is coupled to line 125B and line 125H; the magnetochemical sensor 105C is coupled to line 125C and line 125H; the magnetochemical sensor 105D is coupled to line 125D and line 125H; the magnetochemical sensor 105E is coupled to line 125D and line 125E; the magnetochemical sensor 105F is coupled to line 125D and line 125F; and the magnetochemical sensor 105G is coupled to line 125D and line 125G. In the exemplary embodiment of FIGS. 12A, 12B, and 12C, line 125A, line 125B, line 125C, and line 125D are shown residing over the magnetochemical sensors 105, and line 125E, line 125F, line 125G, and line 125H are shown residing under the magnetochemical sensors 105. FIG. 12B shows the magnetochemical sensor 105E in relation to line 125D and line 125E, the magnetochemical sensor 105F in relation to line 125D and line 125F, the magnetochemical sensor 105G in relation to line 125D and line 125G, and the magnetochemical sensor 105D in relation to line 125D and line 125H. FIG. 12C shows the magnetochemical sensor 105D in relation to line 125D and line 125H, the magnetochemical sensor 105C in relation to line 125C and line 125H, the magnetochemical sensor 105B in relation to line 125B and line 125H, and the magnetochemical sensor 105A in relation to line 125A and line 125H.

The magnetochemical sensors 105 of the exemplary detection device 200A of FIGS. 12A, 12B, and 12C are arranged in a rectangular pattern array 110. (It is to be appreciated that a square pattern is a special case of a rectangular pattern.) Each of the lines 125 identifies a row or a column of the sensor array 110. For example, each of line 125A, line 125B, line 125C, and line 125D identifies a different row of the sensor array 110, and each of line 125E, line 125F, line 125G, and line 125H identifies a different column of the sensor array 110.

The lines 125 may be connected to circuitry that allows the magnetochemical sensors 105 in the sensor array 110 to be read. The circuitry can include, for example, one or more processors as well as other components that are well known in the art (e.g., a current source, etc.). For example, in operation, the circuitry can apply a current to one or more of the lines 125 to detect a characteristic of at least one of the plurality of magnetochemical sensors 105 in the sensor array 110, where the characteristic indicates the presence of a magnetic particle 102 or the absence of any magnetic particle 102 within range of the magnetochemical sensor 105, as explained above.

The magnetochemical sensors 105 and portions of some of the lines 125 (e.g., line 125E, line 125F, line 125G, and line 125H) are illustrated in FIG. 12A using dashed lines to indicate that they are embedded within the detection device 200A. As explained above, the magnetochemical sensors 105 may be protected (e.g., by an insulator) from the contents of the fluid region 150, which itself might be enclosed. Accordingly, it is to be understood that certain of the various illustrated components (e.g., lines 125, sensors 105, etc.) are not necessarily visible in a physical instantiation of the detection device 200A (e.g., they may be embedded in or covered by protective material, such as an insulator).

To simplify the explanation, FIGS. 12A, 12B, and 12C illustrate an exemplary detection device 200A with only sixteen magnetochemical sensors 105 in the sensor array 110, only four functionalized surfaces 116 (namely, functionalized surface 116A, functionalized surface 116B, functionalized surface 116C, and functionalized surface 116D), and eight lines 125. It is to be appreciated that the detection device 200A may have fewer or many more magnetochemical sensors 105 in the sensor array 110, and, accordingly, it may have more or fewer functionalized surfaces 116. Similarly, embodiments that include lines 125 may have more or fewer lines 125. In general, any configuration of magnetochemical sensors 105 and functionalized surfaces 116 that allows the magnetochemical sensors 105 to detect magnetic particles 102 may be used. Similarly, any configuration of one or more lines 125 or some other mechanism that allows the determination of whether the magnetochemical sensors 105 have sensed one or more magnetic particles 102 may be used. The examples presented herein are not intended to be limiting.

Accordingly, FIGS. 12A, 12B, and 12C illustrate a detection device 200A comprising at least one fluid region 150, at least one magnetochemical sensor 105 for detecting magnetic particles 102, at least one line 125 (also referred to herein as an electrode 210) coupled to the at least one magnetochemical sensor 105, and at least one reactive layer 216 situated on the at least one line 125. The at least one reactive layer 216 and the at least one line 125 are situated over the at least one magnetochemical sensor 105. A surface of the reactive layer 216 within the at least one fluid region 150 is functionalized to attract magnetic particles 102, and/or an area of the fluid region 150 that excludes the surface of the reactive layer 216 is functionalized to repel the magnetic particles 102. The reactive layer 216 may comprise any suitable material, such as, for example, one or more of ruthenium (Ru), rhodium (Rh), palladium (Pd), silver (Ag), osmium (Os), iridium (Ir), platinum (Pt), or gold (Ag). The reactive layer 216 may have a thickness of, for example, approximately 1 nm.

In the illustrated embodiment of FIGS. 12A, 12B, and 12C, the layout of the reactive layer 216 within the sensor array 110 is substantially identical to the layout of at least a portion of the lines 125 within the sensor array 110 (because the same mask is used to patten both). In the example of FIGS. 12A, 12B, and 12C, a plurality of magnetochemical sensors 105 are situated in an sensor array 110 that is a rectangular array. Each of the lines 125 is aligned with a row or a column of the rectangular array.

The magnetochemical sensors 105 in the sensor array 110 shown in FIGS. 12A, 12B, and 12C can comprise a ferromagnetic layer 106A, a ferromagnetic layer 106B, and a 107 situated between and coupled to the ferromagnetic layer 106A and the ferromagnetic layer 106B. The magnetochemical sensors 105 may be, for example, MR sensors.

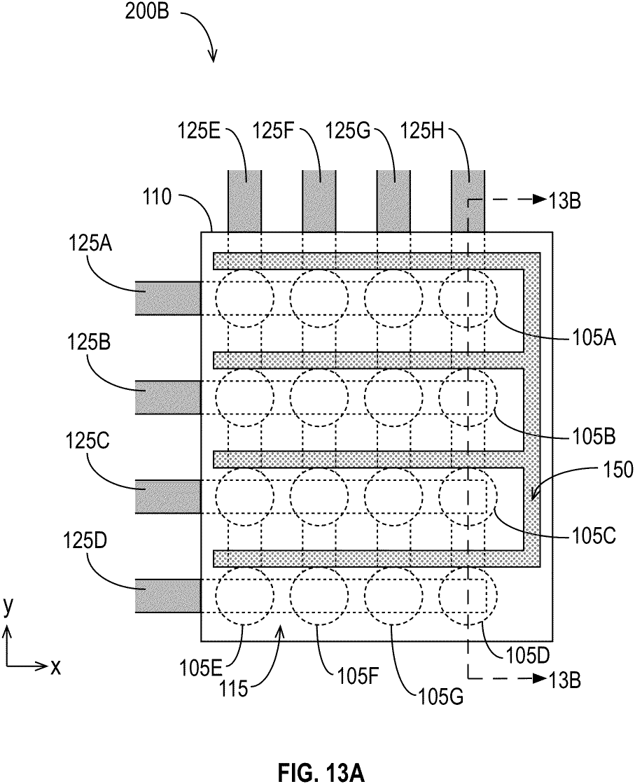

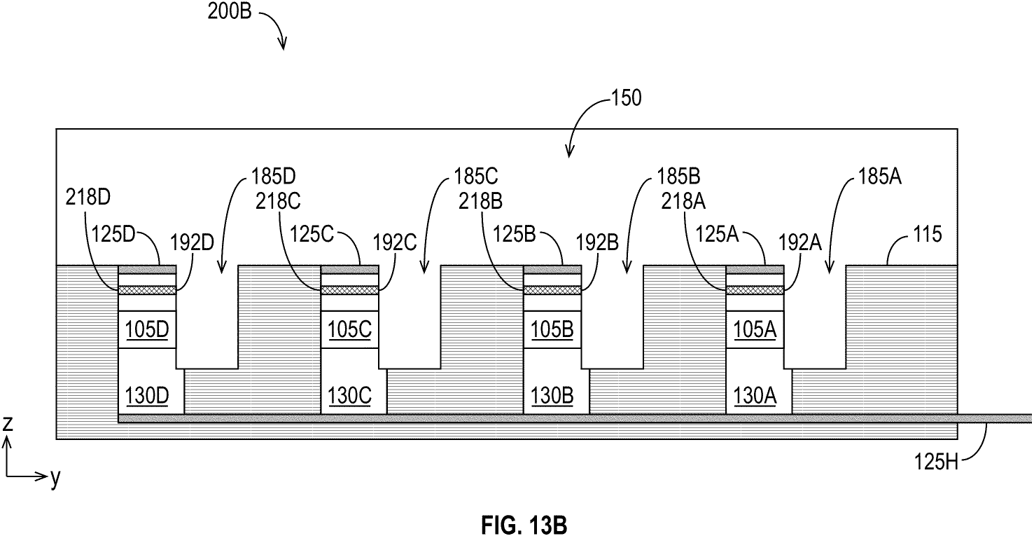

FIGS. 13A and 13B illustrate portions of another example of a detection device 200B that includes a sensor array 110 of magnetochemical sensors 105 in accordance with some embodiments. FIG. 13A is a top view of the detection device 200B (in the plane arbitrarily designated as the x-y plane). As shown in FIG. 13A, the sensor array 110 includes a plurality of magnetochemical sensors 105, with sixteen magnetochemical sensors 105 shown in the sensor array 110 of FIG. 13A. The magnetochemical sensors 105 shown in FIG. 13A may be similar or identical to those described above in the discussion of FIGS. 12A, 12B, and 12C. That description applies to the magnetochemical sensors 105 shown in FIGS. 13A and 13B and is not repeated.

It is to be appreciated that an implementation of a detection device 200B may include any number of magnetochemical sensors 105 (e.g., hundreds, thousands, or more magnetochemical sensors 105). To avoid obscuring the drawing, only seven of the magnetochemical sensors 105 are labeled in FIG. 13A, namely the magnetochemical sensors 105A, 105B, 105C, 105D, 105E, 105F, and 105G. As explained above, the magnetochemical sensors 105 detect the presence or absence of magnetic particles 102. In other words, each of the magnetochemical sensors 105 detects whether there is at least one magnetic particle 102 in its vicinity.

FIG. 13B is a cross-section view (in the x-z plane) of the detection device 200B at the position indicated by the long-dash line labeled “13B” in FIG. 13A. As shown in FIG. 13B, each sensor stack 130 includes a magnetochemical sensor 105 and a reactive layer 218. Specifically, the sensor stack 130A comprises the magnetochemical sensor 105A and the reactive layer 218A; the sensor stack 130B comprises the magnetochemical sensor 105B and the reactive layer 218B; the sensor stack 130C comprises the magnetochemical sensor 105C and the reactive layer 218C; and the sensor stack 130D comprises the magnetochemical sensor 105D and the reactive layer 218D. As explained above, the reactive layer 218 of a sensor stack 130 may be included in a cap layer 112 of the sensor stack 130. The sensor stacks 130 are surrounded by a material which may be, e.g., an electrically-insulating material.

Adjacent to each magnetochemical sensor 105 is a trench 185. Specifically, a trench 185A is adjacent to the magnetochemical sensor 105A, a trench 185B is adjacent to the magnetochemical sensor 105B, a trench 185C is adjacent to the magnetochemical sensor 105C, and a trench 185D is adjacent to the magnetochemical sensor 105D. A region or area within each trench 185 has been functionalized to direct the magnetic particle 102 toward the sensor stack 130 (and the magnetochemical sensor 105). In the example of FIG. 13B, the exposed surfaces of the reactive layers 218 on the sidewalls of the trenches 185 have been functionalized to attract the magnetic particles 102. Specifically, within the trench 185A, a region 192A including the exposed surface of the reactive layer 218A has been functionalized to attract magnetic particles 102; within the trench 185B, a region 192B including the exposed surface of the reactive layer 218B has been functionalized to attract magnetic particles 102; within the trench 185C, a region 192C including the exposed surface of the reactive layer 218C has been functionalized to attract magnetic particles 102; and within the trench 185D, a region 192D including the exposed surface of the reactive layer 218D has been functionalized to attract magnetic particles 102.

As shown in FIG. 13B, the detection device 200B includes a fluid region 150. The fluid region 150 of the example detection device 200B is similar to that described above for the detection device 200A. That description applies to the fluid region 150 of the detection device 200B and is not repeated here.

It is to be understood that, as described above, different areas within the trenches 185 of the detection device 200B can be functionalized differently. For example, some areas (e.g., the exposed surfaces of the reactive layers 218) can be functionalized to attract magnetic particles 102, and other areas (e.g., the portions of the trench 185 sidewalls excluding the reactive layer 216 and/or the surface 115) can be functionalized to repel magnetic particles 102. In some embodiments, at least one portion of at least one trench 185 sidewall and/or the surface 115 is functionalized as described above (e.g., to attract or repel magnetic particles 102).

FIG. 13B illustrates an enclosed fluid region 150 with a top portion that extends in the x-y plane, but there is no requirement for the fluid region 150 to be enclosed. In some embodiments, the surface of the fluid region 150 has properties and characteristics that protect the magnetochemical sensors 105 from whatever fluids are in the fluid region 150, while still allowing the magnetochemical sensors 105 to detect magnetic particle 102 that are nearby (e.g., on one of the functionalized surfaces 116).

As shown in FIG. 13A and13B, the example detection device 200B includes a number of lines 125. The lines 125 and circuitry to which they may coupled was described above in the discussion of FIGS. 12A, 12B, and 12C. That discussion applies here and is not repeated.

The magnetochemical sensors 105 and portions of the lines 125 are illustrated in FIG. 13A using dashed lines to indicate that they are embedded within the detection device 200B. As explained above, the magnetochemical sensors 105 may be protected (e.g., by an insulator) from the contents of the fluid region 150, which itself might be enclosed. Accordingly, it is to be understood that certain of the various illustrated components (e.g., lines 125, sensors 105, etc.) are not necessarily visible in a physical instantiation of the detection device 200B (e.g., they may be embedded in or covered by protective material, such as an insulator).

To simplify the explanation, FIGS. 13A and 13B illustrate portions of an exemplary detection device 200B with only sixteen magnetochemical sensors 105 in the sensor array 110 and eight lines 125. It is to be appreciated that the detection device 200B may have fewer or many more magnetochemical sensors 105 in the sensor array 110 and, correspondingly, more or fewer other features (e.g., lines 125, trenches 185, etc.). The examples presented herein are not intended to be limiting.

FIG. 13A illustrates the four trenches 185 (labeled in FIG. 13B as trench 185A trench 185B, trench 185C, and trench 185D) as being connected. It is to be appreciated that the trenches 185 need not be connected. In other words, they can be separate and can hold separate quantities of fluids.

Thus, FIGS. 13A and 13B illustrate an example detection device 200B that comprises a plurality of sensor stacks 130 and a plurality of electrodes (the lines 125) for reading the magnetochemical sensors 105 included in the sensor stacks 130. A sensor stack 130 in the detection device 200B can include a ferromagnetic layer 106A, a ferromagnetic layer 106B, a nonmagnetic spacer layer 107 situated between ferromagnetic layer 106A and the ferromagnetic layer 106B, and a reactive layer 218. The reactive layer 218 may be situated, for example, in a cap layer 112 of the sensor stack 130. The cap layer 112 may comprise a first metal layer (e.g., Ru), a second metal layer (e.g., Ru), a third metal layer (e.g., Ta), and the reactive layer 218, where the third metal layer and the reactive layer 218 are situated between the first and second metal layers. As explained above, the reactive layer 218 may comprise any suitable material, such as, for example, one or more of ruthenium (Ru), rhodium (Rh), palladium (Pd), silver (Ag), osmium (Os), iridium (Ir), platinum (Pt), or gold (Ag). The reactive layer 218 may have a thickness of, for example, approximately 1 nm.

The detection device 100B also has a plurality of trenches 185 adjacent to the sensor stacks 130 and exposing surfaces of the reactive layers 218. A surface within each trench 185 is functionalized to direct magnetic particles 102 toward a sensor stack 130. For example, the exposed surfaced of the reactive layer 218 within a trench 185 may be functionalized to attract magnetic particles 102. There may be multiple functionalized zones within each trench 185. For example, if a first zone includes the exposed surface of the reactive layer 218, a second zone that excludes the first zone can be functionalized to repel magnetic particles 102.

The example detection device 200B of FIGS. 13A and 13B also includes a plurality of electrodes 210, namely, the lines 125. The reactive layers 218 are situated between the magnetochemical sensors 105 and the upper electrodes 210 (e.g., line 125A, line 125B, line 125C, and line 125D).

The reactive layers 218 are illustrated situated above the magnetochemical sensors 105 in FIG. 13B. As explained above in the discussion of FIGS. 11A and 11B, it is to be understood that the reactive layers 218 could alternatively be situated under the magnetochemical sensors 105. Furthermore, although FIG. 13B illustrates only one reactive layer 218 per magnetochemical sensor 105, it is possible for an embodiment to include multiple reactive layers 218 with surfaces exposed within the trench 185. For example, an embodiment may include a first reactive layer 218 below a magnetochemical sensor 105 and a second reactive layer 218 over the magnetochemical sensor 105. The exposed surfaces of both reactive layers 218 may be functionalized to attract magnetic particles 102. As described previously, there may be multiple functionalized zones within the trench 185, including one or more zones (e.g., above and/or below and/or laterally displaced from the reactive layers 218) that are functionalized to repel magnetic particles 102.

The detection devices described herein can be fabricated from a wafer by applying a mask to protect the regions under the mask. Material can then be removed from the portion of the wafer that is not protected by the mask. There are many ways to accomplish the removal, such as, for example, by etching the layer from a direction perpendicular to the layer or by using an ion mill with ions aimed at the layer in the z-direction. As a result of the removal of material from the wafer, only the portion of the layer protected by the mask remains intact.

FIG. 14 is a flow diagram illustrating an example of a method 300 of making a detection device in accordance with some embodiments. At block 302, the method 300 begins. At block 304, a sensor stack 130 is deposited, for example, on a substrate of a wafer. The sensor stack 130 may comprise, for example, a magnetochemical sensor 105 and other layers described herein (e.g., a cap layer 112). At block 306, a mask is situated over the wafer, exposing the sensor stack 130. At block 308, an electrode 210 (or a lines 125) is deposited over the sensor stack 130. At block 310, while the mask remains in place, a reactive layer 216 is deposited over the electrode 210. As explained above, because the reactive layer 216 is deposited using the same mask as is used to deposit the electrode 210, the reactive layer 216 is as aligned with the magnetochemical sensor 105 in the sensor stack 130 as the electrode 210 is. At block 312, the reactive layer 216 is functionalized (e.g., as described above) to attract magnetic particles 102. Optionally, at block 314, another area of the surface 115 of a fluid region 150 of the detection device is functionalized to repel magnetic particles 102 (e.g., a portion of the surface 115 that does not include the reactive layer 216). At block 316, the method 300 ends.

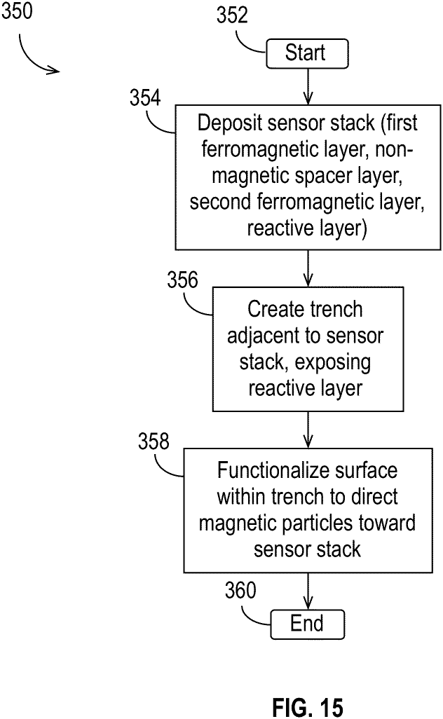

FIG. 15 is a flow diagram illustrating another example of a method 350 of making a detection device in accordance with some embodiments. At block 352, the method 300 begins. At block 354, a sensor stack 130 is deposited, for example, on a substrate of a wafer. The sensor stack 130 may comprise, for example, a ferromagnetic layer 106A, a ferromagnetic layer 106B, a nonmagnetic spacer layer 107 situated between the ferromagnetic layer 106A and the ferromagnetic layer 106B, and a reactive layer 218 comprising a reactive metal. The reactive layer 218 may be deposited after the ferromagnetic layer 106A, nonmagnetic spacer layer 107, and ferromagnetic layer 106B have been deposited. The reactive layer 218 may be embedded in a cap layer 112 of the detection device 200B. An electrode 210 may be deposited over the cap layer 112.

At block 356, a trench 185 is created adjacent to the sensor stack 130. The trench 185 exposes a surface of the reactive layer 218. At block 358, a surface within the trench 185 is functionalized (e.g., as described above) to direct (or draw) magnetic particles 102 toward the sensor stack 130. As explained above, the exposed surface of the reactive layer 218 can be functionalized to attract magnetic particles 102. Other surfaces within the 185 can be functionalized to repel magnetic particles 102 to assist in directing them toward the magnetochemical sensor 105 in the sensor stack 130. Generally, functionalizing the surface within the trench 185 comprises functionalizing a first zone to attract magnetic particles 102, where the first zone includes the exposed surface of the reactive layer 218, and/or functionalizing a second zone to repel the magnetic particles 102, where the second zone excludes the exposed surface of the reactive layer 218. The first and second zones may be non-overlapping either throughout the fabrication process or at the end of the process. (For example, a portion of the first zone may be affected by later functionalization of the second zone, or vice versa.) At block 360, the method 350 ends.

It is to be appreciated that various of the disclosed example embodiments may be combined. For example, an implementation may include one or more reactive layers 216 above and/or below a magnetochemical sensor 105 as shown and described (e.g., in the context of FIGS. 9A and 9B), and one or more reactive layers 218 to the side of the magnetochemical sensor 105 as shown and described (e.g., in the context of FIGS. 11A and 11B). The example embodiments shown and described herein are not intended to be exhaustive, exclusive, or limiting.

In the foregoing description and in the accompanying drawings, specific terminology has been set forth to provide a thorough understanding of the disclosed embodiments. In some instances, the terminology or drawings may imply specific details that are not required to practice the invention.

To avoid obscuring the present disclosure unnecessarily, well-known components are shown in block diagram form and/or are not discussed in detail or, in some cases, at all.

Unless otherwise specifically defined herein, all terms are to be given their broadest possible interpretation, including meanings implied from the specification and drawings and meanings understood by those skilled in the art and/or as defined in dictionaries, treatises, etc. As set forth explicitly herein, some terms may not comport with their ordinary or customary meanings.

As used in the specification and the appended claims, the singular forms “a,” “an” and “the” do not exclude plural referents unless otherwise specified. The word “or” is to be interpreted as inclusive unless otherwise specified. Thus, the phrase “A or B” is to be interpreted as meaning all of the following: “both A and B,” “A but not B,” and “B but not A.” Any use of “and/or” herein does not mean that the word “or” alone connotes exclusivity.

As used in the specification and the appended claims, phrases of the form “at least one of A, B, and C,” “at least one of A, B, or C,” “one or more of A, B, or C,” and “one or more of A, B, and C” are interchangeable, and each encompasses all of the following meanings: “A only,” “B only,” “C only,” “A and B but not C,” “A and C but not B,” “B and C but not A,” and “all of A, B, and C.”

To the extent that the terms “include(s),” “having,” “has,” “with,” and variants thereof are used in the detailed description or the claims, such terms are intended to be inclusive in a manner similar to the term “comprising,” i.e., meaning “including but not limited to.”

The terms “exemplary” and “embodiment” are used to express examples, not preferences or requirements.

The term “coupled” is used herein to express a direct connection/attachment as well as a connection/attachment through one or more intervening elements or structures.

The terms “over,” “under,” “between,” and “on” are used herein refer to a relative position of one feature with respect to other features. For example, one feature disposed “over” or “under” another feature may be directly in contact with the other feature or may have intervening material. Moreover, one feature disposed “between” two features may be directly in contact with the two features or may have one or more intervening features or materials. In contrast, a first feature “on” a second feature is in contact with that second feature.

The term “substantially” is used to describe a structure, configuration, dimension, etc. that is largely or nearly as stated, but, due to manufacturing tolerances and the like, may in practice result in a situation in which the structure, configuration, dimension, etc. is not always or necessarily precisely as stated. For example, describing two lengths as “substantially equal” means that the two lengths are the same for all practical purposes, but they may not (and need not) be precisely equal at sufficiently small scales. As another example, a structure that is “substantially vertical” would be considered to be vertical for all practical purposes, even if it is not precisely at 90 degrees relative to horizontal.

The drawings are not necessarily to scale, and the dimensions, shapes, and sizes of the features may differ substantially from how they are depicted in the drawings.

Although specific embodiments have been disclosed, it will be evident that various modifications and changes may be made thereto without departing from the broader spirit and scope of the disclosure. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

1. A detection device, comprising:
a fluid region;
a magnetochemical sensor for detecting magnetic particles; and
an electrode coupled to the magnetochemical sensor, the electrode for reading the magnetochemical sensor, wherein:
(a) a reactive layer is situated on the electrode, and a surface of the reactive layer within the fluid region is functionalized to attract the magnetic particles, or
(b) an area of the fluid region that is not situated over the electrode is functionalized to repel the magnetic particles, or
(c) both (a) and (b).

2. The detection device recited in claim 1, wherein the reactive layer is situated on the electrode, and the surface of the reactive layer within the fluid region is functionalized to attract the magnetic particles, and wherein a layout of the reactive layer is substantially identical to a layout of the electrode.

3. The detection device recited in claim 2, wherein the magnetochemical sensor is one of a plurality of magnetochemical sensors included in the detection device.

4. The detection device recited in claim 3, wherein the plurality of magnetochemical sensors is arranged in a rectangular array, and wherein the electrode is aligned with a row or a column of the rectangular array.

5. The detection device recited in claim 1, wherein the reactive layer is situated on the electrode, and the surface of the reactive layer within the fluid region is functionalized to attract the magnetic particles, and wherein the reactive layer comprises one or more of ruthenium (Ru), rhodium (Rh), palladium (Pd), silver (Ag), osmium (Os), iridium (Ir), platinum (Pt), or gold (Ag).

6. The detection device recited in claim 1, wherein the magnetochemical sensor comprises:
a first ferromagnetic layer;
a second ferromagnetic layer; and
a spacer layer situated between and coupled to the first ferromagnetic layer and the second ferromagnetic layer.

7. The detection device recited in claim 1, wherein the magnetochemical sensor comprises a magnetoresistive sensor.

8. The detection device recited in claim 1, wherein the reactive layer is situated on the electrode, and the surface of the reactive layer within the fluid region is functionalized to attract the magnetic particles, and wherein the electrode and the reactive layer are situated over the magnetochemical sensor.

9. A method of fabricating a device for detecting magnetic particles, the method comprising:
depositing a sensor stack on a wafer;
situating a mask over the wafer;
depositing an electrode over the sensor stack;
while the mask is in place, depositing a reactive layer over the electrode; and
functionalizing the reactive layer to attract the magnetic particles to the reactive layer.

10. The method of claim 9, further comprising:
functionalizing an area of a surface within a fluid region of the device to repel the magnetic particles, wherein the area excludes the reactive layer.

11. A detection device for detecting magnetic particles, comprising:
a sensor stack, comprising:
a magnetochemical sensor, and
a reactive layer;
a trench adjacent to the sensor stack and exposing the reactive layer; and
a functionalized surface within the trench, wherein the functionalized surface is configured to direct the magnetic particles toward the sensor stack.

12. The detection device recited in claim 11, wherein the reactive layer is situated in a cap layer of the sensor stack, and the functionalized surface within the trench comprises a surface of the reactive layer exposed to the trench.

13. The detection device recited in claim 11, wherein the sensor stack further comprises a cap layer, wherein the cap layer comprises:
a first metal layer,
a second metal layer,
a third metal layer, and
the reactive layer,
wherein the third metal layer and the reactive layer are situated between the first metal layer and the second metal layer.

14. The detection device recited in claim 13, wherein:
the first metal layer and the second metal layer comprise ruthenium (Ru),
the third metal layer comprises tantalum (Ta), and
the reactive layer comprises one or more of ruthenium (Ru), rhodium (Rh), palladium (Pd), silver (Ag), osmium (Os), iridium (Ir), platinum (Pt), or gold (Ag).

15. The detection device recited in claim 11, wherein the reactive layer comprises one or more of ruthenium (Ru), rhodium (Rh), palladium (Pd), silver (Ag), osmium (Os), iridium (Ir), platinum (Pt), or gold (Ag).

16. The detection device recited in claim 11, further comprising an electrode, and wherein the reactive layer is situated between the magnetochemical sensor and the electrode.

17. The detection device recited in claim 11, wherein the functionalized surface includes an exposed surface of the reactive layer, and wherein the functionalized surface is functionalized to attract the magnetic particles.

18. The detection device recited in claim 11, wherein the functionalized surface comprises a first zone functionalized to attract the magnetic particles and a second zone functionalized to repel the magnetic particles, and wherein an exposed surface of the reactive layer is included in the first zone.

19. A method of fabricating a device for detecting magnetic particles, the method comprising:
depositing a sensor stack, the sensor stack comprising:
a first ferromagnetic layer,
a second ferromagnetic layer,
a non-magnetic spacer layer situated between the first ferromagnetic layer and the second ferromagnetic layer, and
a reactive layer comprising a reactive metal;
creating a trench adjacent to the sensor stack, thereby exposing the reactive layer; and
functionalizing a surface within the trench to direct the magnetic particles toward the sensor stack.

20. The method of claim 19, wherein the reactive layer is deposited after depositing the first ferromagnetic layer, the non-magnetic spacer layer, and the second ferromagnetic layer.

21. The method of claim 19, wherein the reactive layer is embedded in a cap layer of the sensor stack, and further comprising:
depositing an electrode over the cap layer.

22. The method of claim 19, wherein functionalizing the surface within the trench to direct the magnetic particles toward the sensor stack comprises at least one of (a) functionalizing a first zone to attract the magnetic particles, the first zone including an exposed surface of the reactive layer, or (b) functionalizing a second zone to repel the magnetic particles, wherein the second zone excludes the exposed surface of the reactive layer.

23. The method of claim 22, wherein the first zone and the second zone are nonoverlapping.
